(19) United States
(12) Patent Application Publication
(10) Pub. No.: US 2024/0397713 A1
(43) Pub. Date: Nov. 28, 2024

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Rho Gyu KWAK, Gyeonggi-do (KR); Jung Shik JANG, Gyeonggi-do (KR); In Su PARK, Gyeonggi-do (KR); Na Yeong YANG, Gyeonggi-do (KR); Seok Min CHOI, Gyeonggi-do (KR); Won Geun CHOI, Gyeonggi-do (KR); Jung Dal CHOI, Gyeonggi-do (KR)

(21) Appl. No.: 18/464,268

(22) Filed: Sep. 11, 2023

(30) Foreign Application Priority Data
May 24, 2023 (KR) 10-2023-0066903

(51) Int. Cl. H10B 43/27; H10B 41/27; H10B 41/40; H10B 43/40

(52) U.S. Cl. CPC H10B 43/27; H10B 41/27; H10B 41/40; H10B 43/40

(57) ABSTRACT

A semiconductor device may include a gate structure, a source structure that is disposed on the gate structure, channel structures that extend into the source structure through the gate structure and include a channel layer and a memory layer surrounding the channel layer, the memory layer including a cut area that exposes the channel layer, and a slit structure that extends into the source structure through the gate structure between the channel structures, an upper surface of the slit structure being disposed at a lower level than the cut area.

### CROSS-REFERENCE TO RELATED APPLICATION

This application claims priority under 35 U.S.C. § 119 to Korean Patent Application No. 10-2023-0066903 filed on May 24, 2023, which is incorporated herein by reference in its entirety.

### BACKGROUND

### 1. Technical Field

Embodiments of the present disclosure relate to an electronic device and a method of manufacturing an electronic device and, more particularly, to a semiconductor device and a method of manufacturing a semiconductor device.

### 2. Related Art

The degree of integration of semiconductor devices is basically determined by the area that is occupied by a unit memory cell. As the improvement of the degree of integration of semiconductor devices in which a memory cell is formed on a substrate as a single layer reaches its limit, a three-dimensional semiconductor device in which memory cells are stacked on a substrate is proposed. Furthermore, in order to improve operation reliability of such a semiconductor device, various structures and manufacturing methods are being developed.

### SUMMARY

In an embodiment of the present disclosure, a semiconductor device may include a gate structure, a source structure that is disposed on the gate structure, channel structures that extend into the source structure through the gate structure and include a channel layer and a memory layer surrounding the channel layer, the memory layer including a cut area that exposes the channel layer, and a slit structure that extends into the source structure through the gate structure between the channel structures, an upper surface of the slit structure being disposed at a lower level than the cut area.

In an embodiment of the present disclosure, a method of manufacturing a semiconductor device may include forming a source structure including a source sacrificial layer over a substrate, forming a stack by alternately stacking first material layers and second material layers on a first side of the source structure, forming channel structures that extend into the source structure through the stack, removing the substrate, forming a first opening that exposes the source sacrificial layer through a second side of the source structure, forming a second opening by removing the source sacrificial layer through the first opening, and forming a third source layer within the second opening and the first opening.

### BRIEF DESCRIPTION OF THE DRAWINGS

FIGS. 1A and 1B are diagrams for describing a semiconductor device according to an embodiment of the present disclosure.

FIGS. 2A to 2I are diagrams for describing a method of manufacturing a semiconductor device according to an embodiment of the present disclosure.

### DETAILED DESCRIPTION

Hereinafter, embodiments according to the technical spirit of the present disclosure are described with reference to the accompanying drawings.

Embodiments of the present disclosure provide a semiconductor device having a stable structure and improved characteristics and a method of manufacturing a semiconductor device having a stable structure and improved characteristics.

According to embodiments of the present disclosure, a semiconductor device having a stable structure and improved reliability can be provided.

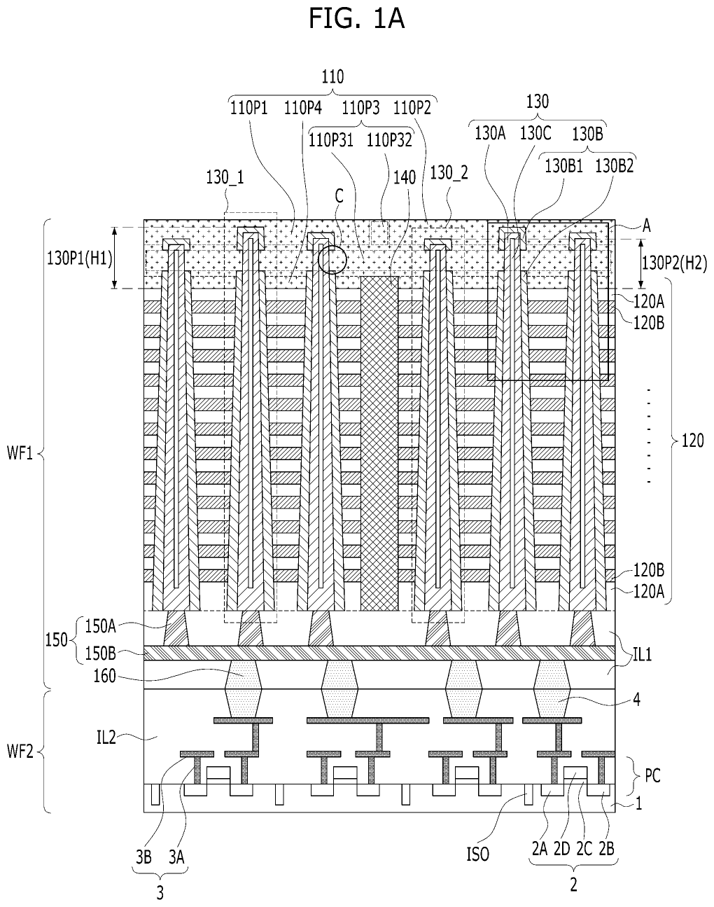

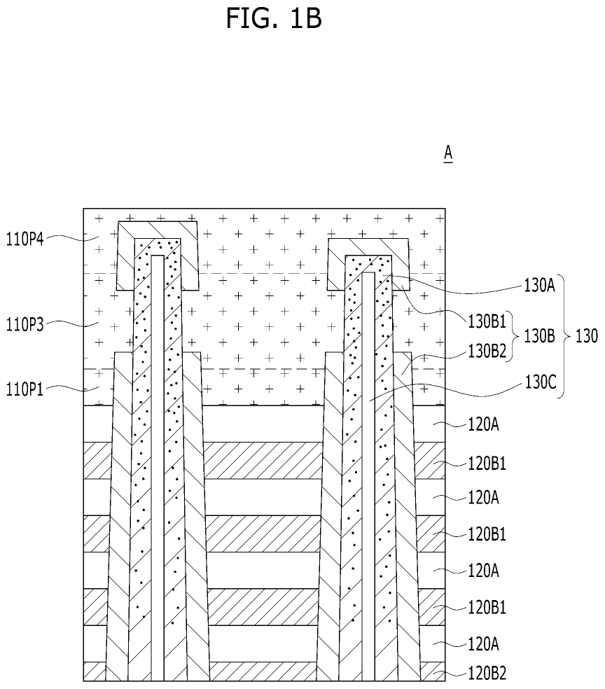

FIGS. 1A and 1B are diagrams for describing a semiconductor device according to an embodiment of the present disclosure. FIG. 1B is an enlarged view of an area ‘A’ in FIG. 1A.

Referring to FIG. 1A, the semiconductor device may include at least one of a first wafer WF1 and a second wafer WF2. In this case, each of the wafers WF1 and WF2 may denote a structure which includes a substrate or does not include a substrate. In an embodiment, each of the wafers WF1 and WF2 may denote a structure which does not includes a substrate and includes various components, for example, channel structures 130, a gate structure 120, etc. The first wafer WF1 may denote a first semiconductor structure which includes at least one of a source structure 110, the gate structure 120, the channel structures 130, or a slit structure 140. The first wafer WF1 may further include at least one of an interconnection structure 150, a bonding pad 160, or an interlayer insulating layer IL1.

The gate structure 120 may include insulating layers 120A and conductive layers 120B that are alternately stacked. In this case, each of the conductive layers 120B may be used as a source selection line, a drain selection line, a word line, or a bit line. The insulating layers 120A may include an insulating material such as oxide. The conductive layers 120B may include a conductive material, such as tungsten, molybdenum, or polysilicon.

The channel structures 130 may be extended into the source structure 110 through the gate structure 120. In this case, the source structure 110 may be disposed on the gate structure 120. Each of the channel structures 130 may include at least one of a channel layer 130A, a memory layer 130B, and an insulating core 130C. The memory layer 130B may surround the channel layer 130A. The insulating core 130C may be disposed within the channel layer 130A. The memory layer 130B may include a first memory pattern 130B1 and a second memory pattern 130B2. The first memory pattern 130B1 and the second memory pattern 130B2 may be spaced apart from each other. The first memory pattern 130B1 may be disposed between the source structure 110 and the channel layer 130A. The second memory pattern 130B2 may be disposed between the gate structure 120 and the channel layer 130A. The memory layer 130B may include a cut area C that exposes the channel layer 130A. The cut area C may denote an area between the first memory pattern 130B1 and the second memory pattern 130B2. The cut areas C of the channel structures 130 may be disposed substantially at the same level (i.e., height). The channel layer 130A and the source structure 110 may be in contact with through the cut area C.

Each of the channel structures 130 may include at least one of a first channel structure 130_1 and a second channel structure 130_2. The first channel structure 130_1 may include a first protruding part 130P1 having a first height H1. The second channel structure 130_2 may include a second protruding part 130P2 having a second height H2. The first protruding part 130P1 and the second protruding part 130P2 may protrude into the source structure 110. The first height H1 and the second height H2 may be substantially the same or may be different from each other. For example, the first height H1 and the second height H2 may be different from each other. The second height H2 may be smaller than the first height H1. Each of the first protruding part 130P1 and the second protruding part 130P2 may include at least one of the channel layer 130A, the memory layer 130B, and the insulating core 130C. The heights of the channel layer 130A, the memory layer 130B, and the insulating core 130C that protrude into the source structure 110 may be different from one another. For example, the heights of the channel layer 130A of the first protruding part 130P1 and the channel layer 130A of the second protruding part 130P2 may be different from each other. The heights of the memory layer 130B of the first protruding part 130P1 and the memory layer 130B of the second protruding part 130P2 may be different from each other. The heights of the insulating core 130C of the first protruding part 130P1 and the insulating core 130C of the second protruding part 130P2 may be different from each other. For reference, the channel structures 130 may include the plurality of first channel structures 130_1 and the plurality of second channel structures 130_2 having different heights. The heights of the protruding parts 130P1 and 130P2 of the channel structures 130 may also be different from each other.

The source structure 110 may be disposed on the gate structure 120. The source structure 110 may include polysilicon. The source structure 110 may include a first part 110P1, a second part 110P2, a third part 110P3, and a fourth part 110P4. The first part 110P1 and the second part 110P2 may be spaced apart from each other. The third part 110P3 may protrude between the first part 110P1 and the second part 110P2. The third part 110P3 may include a horizontal part 110P31 that extends between the first part 110P1 and the gate structure 120 and between the second part 110P2 and the gate structure 120. The third part 110P3 may include a vertical part 110P32 that protrudes from the horizontal part 110P31 between the first part 110P1 and the second part 110P2. The vertical part 110P32 may have a cross section having a form in which the width of the vertical part 110P32 is uniform, but the present disclosure is not limited thereto. The vertical part 110P32 may have a cross section having a tapered form. The fourth part 110P4 may be disposed between the third part 110P3 and the gate structure 120.

The source structure 110 may surround the channel structures 130. For example, the source structure 110 may surround the protruding parts 130P1 and 130P2 of the channel structures 130. The first part 110P1 may surround the first protruding part 130P1 of the first channel structure 130_1. The second part 110P2 may surround the second protruding part 130P2 of the second channel structure 130_2. For example, the first part 110P1 and/or the second part 110P2 may surround the first memory pattern 130B1. The third part 110P3 may be connected to the first channel structure 130_1 and the second channel structure 130_2. For example, the third part 110P3 may be in contact with the first channel structure 130_1 and the second channel structure 130_2 through the horizontal part 110P31. In this case, the third part 110P3 may be connected to the channel layer 130A of the channel structures 130.

In a process of forming the third part 110P3, impurities may be diffused into the channel structures 130. For example, in a process of forming the third part 110P3, polysilicon including impurities may be formed, and the impurities may be diffused into the channel layer 130A of each of the channel structures 130 through the cut area C. Accordingly, a junction may be formed within the channel layer 130A of each of the channel structures 130 having different heights.

Referring to FIG. 1B, each of the channel structures 130 may constitute a memory string. The gate structure 120 may include the conductive layers 120B that are connected to a memory string. Each of the conductive layers 120B may be used as a word line, a source selection line, a drain selection line, or a bit line. If the channel structures 130 have different heights, the types and numbers of conductive layers 120B that are used within the gate structure 120 may be different depending on the heights of the channel structures 130. For example, the number of source selection lines may be relatively small and the number of word lines may be many in a memory string having a small height. In contrast, the number of source selection lines may be relatively many and the number of word lines may be small in a memory string having a great height. Accordingly, the types and numbers of conductive layers 120B that are used for each memory string within one gate structure 120 may be different.

However, in the present disclosure, the junctions may be formed within the channel layers 130A through the cut areas C of the channel structures 130, respectively, which are disposed substantially at the same level. In other words, the junctions that are formed within the channel layers 130A may be disposed substantially at the same level. Accordingly, although the heights of the channel structures 130 are different, the types and numbers of conductive layers 120B that are used in a memory string may be the same. For example, the number of source selection lines 120B1 that are used in a memory string may be the same. Each of the remaining conductive layers 120B may be used as a word line 120B2 or a drain selection line.

The slit structure 140 may be extended through the gate structure 120. For example, the slit structure 140 may be extended into the source structure 110 through the gate structure 120 between the channel structures 130. An upper surface of the slit structure 140 may be disposed substantially at the same level as an upper surface of the fourth part 110P4. For example, the upper surface of the slit structure 140 may be disposed at a level lower than the level of the cut area C. The slit structure 140 may be an insulating layer that is formed within a slit (not illustrated) for substituting sacrificial layers (not illustrated) with the conductive layers 120B in a process of manufacturing the semiconductor device. Alternatively, the slit structure 140 may include a source contact structure that is connected to the source structure 110.

The interconnection structure 150 may be disposed within the interlayer insulating layer IL1, and may be disposed under the channel structures 130. The interconnection structure 150 may include at least one of a contact via 150A and a wire 150B. The contact vias 150A may be connected to the channel structures 130, respectively. The wire 150A may connect the contact vias 150A. Each of the contact vias 150A and the wire 150A may include a conductive material, such as tungsten.

The bonding pad 160 may be disposed within the interlayer insulating layer IL1, and may be disposed under the interconnection structure 150. The bonding pads 160 may be connected to the wire 150A, and may be electrically connected to the channel structures 130 through the interconnection structure 150. The bonding pad 160 may include a conductive material, such as tungsten.

The second wafer WF2 may include a peripheral circuit PC. The second wafer WF2 may denote a second semiconductor structure including the peripheral circuit PC. The second wafer WF2 may further include an interconnection structure 3, a bonding pad 4, or an interlayer insulating layer IL2 or may further include the interconnection structure 3, the bonding pad 4, or the interlayer insulating layer IL2 in combination.

The peripheral circuit PC may be disposed on a substrate 1. An isolation layer ISO may be disposed within the substrate 1. An active area may be defined by the isolation layer ISO. The peripheral circuit PC may include a transistor 2, a capacitor, or a register. For example, the transistor 2 may include a first junction (i.e., a source junction) 2A, a second junction (i.e., a drain junction) 2B, a gate insulating layer 2C, or a gate electrode 2D. The gate insulating layer 2C may be disposed between the gate electrode 2D and the substrate 1. Each of the gate insulating layer 2C and the isolation layer ISO may include an insulating material, such as oxide or nitride.

The interconnection structure 3 may include contact vias 3A or wires 3B. The interlayer insulating layer IL2 may be disposed on the substrate 1. The interconnection structure 3 may be disposed within the interlayer insulating layer IL2. The interconnection structure 3 may be electrically connected to the peripheral circuit PC. The contact vias 3A may connect the junctions 2A and 2B of the transistor 2 with the wires 3B, and may connect the wires 3B with each other. Each of the contact vias 3A and the wires 3B may include a conductive material, such as aluminum, copper, or tungsten.

The bonding pad 4 may be disposed within the interlayer insulating layer IL2, and may be disposed on the interconnection structure 3. The bonding pads 4 may be connected to the wires 3B, and may be electrically connected to the peripheral circuit PC through the interconnection structure 3. The bonding pad 4 may include a conductive material, such as tungsten.

The first wafer WF1 and the second wafer WF2 may be bonded to each other. For example, the bonding pads 160 of the first wafer WF1 and the bonding pads 4 of the second wafer WF2 may be bonded, respectively. Accordingly, the first wafer WF1 may be disposed on the second wafer WF2. In this case, the top of the second wafer WF2 and the top of the first wafer WF1 may be bonded in the state in which the first wafer WF1 has been rotated.

For reference, in this case, the terms “top” and bottom” and “over” and “under” may be relative concepts for convenience of description. The source structure 110 may be disposed under the gate structure 120. Alternatively, the second wafer WF2 may be disposed on the first wafer WF1. Accordingly, the top of the second wafer WF2 and the top of the first wafer WF1 may be bonded in the state in which the second wafer WF2 has been rotated.

According to the aforementioned structure, although the channel structures 130 have different heights, the junctions formed within the channel layers 130A of the channel structures 130, respectively, may be disposed substantially at the same level. Accordingly, the number of source selection lines 120B1 corresponding to each memory string within the gate structure 120 may be the same.

Furthermore, the degree of integration of memory in semiconductor devices can be increased by separately forming the first wafer WF1 including a cell array and the second wafer WF2 including the peripheral circuit PC.

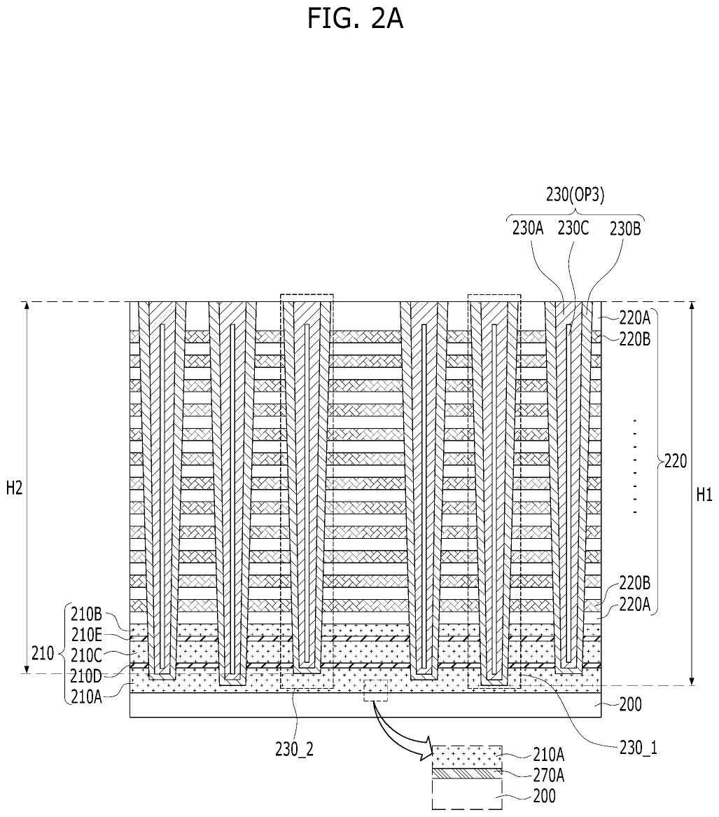

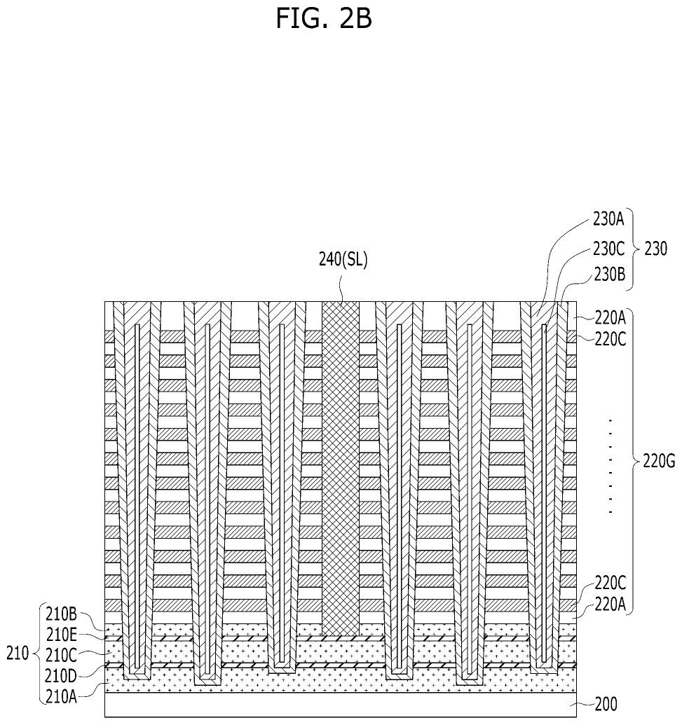

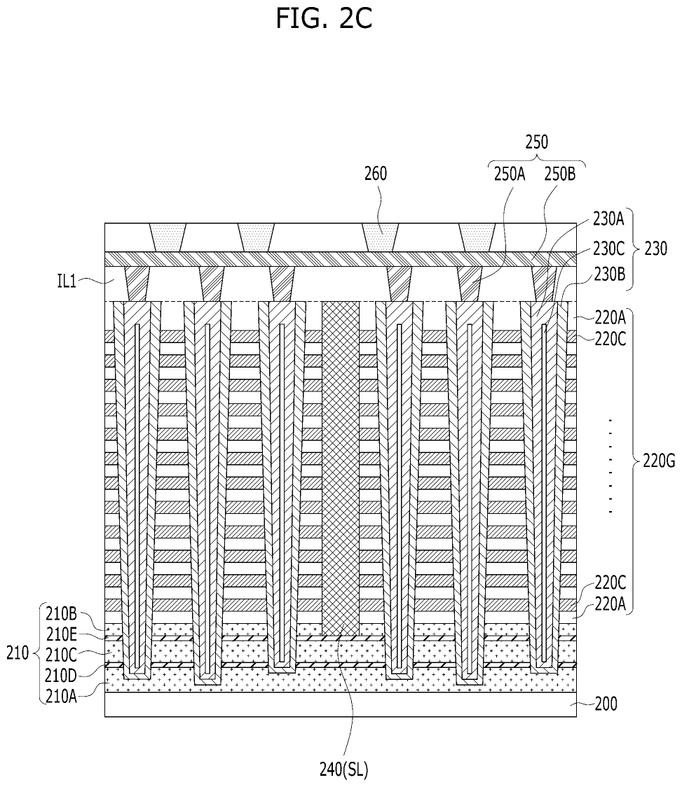

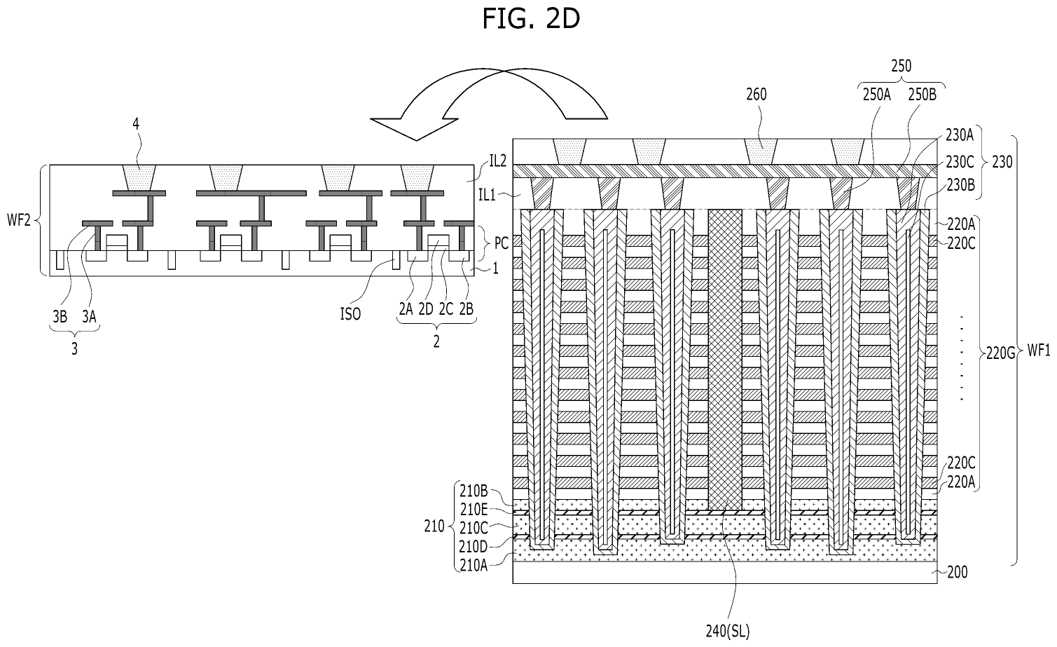

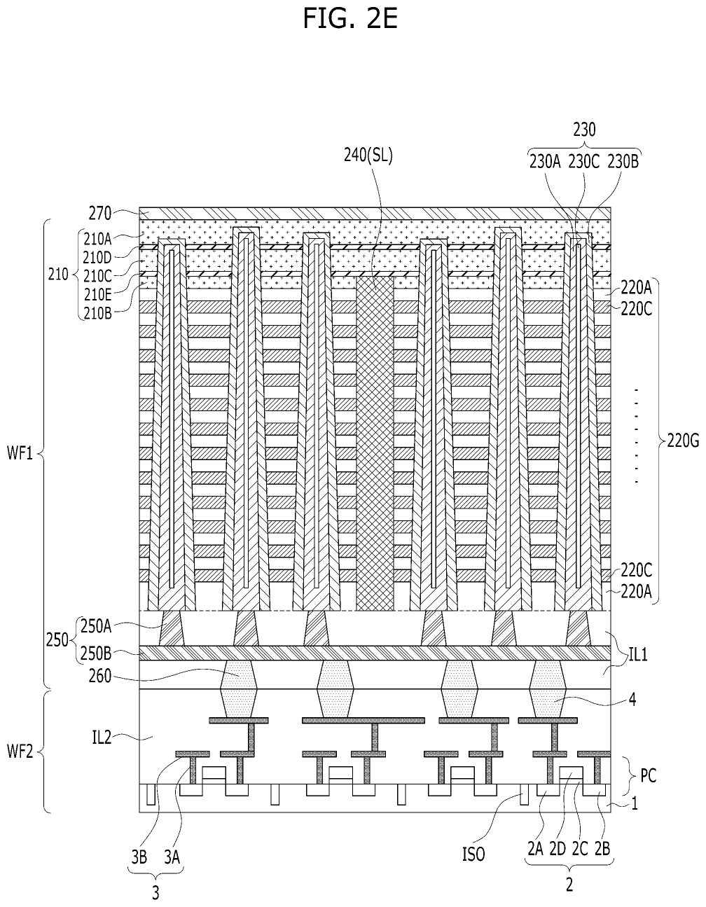

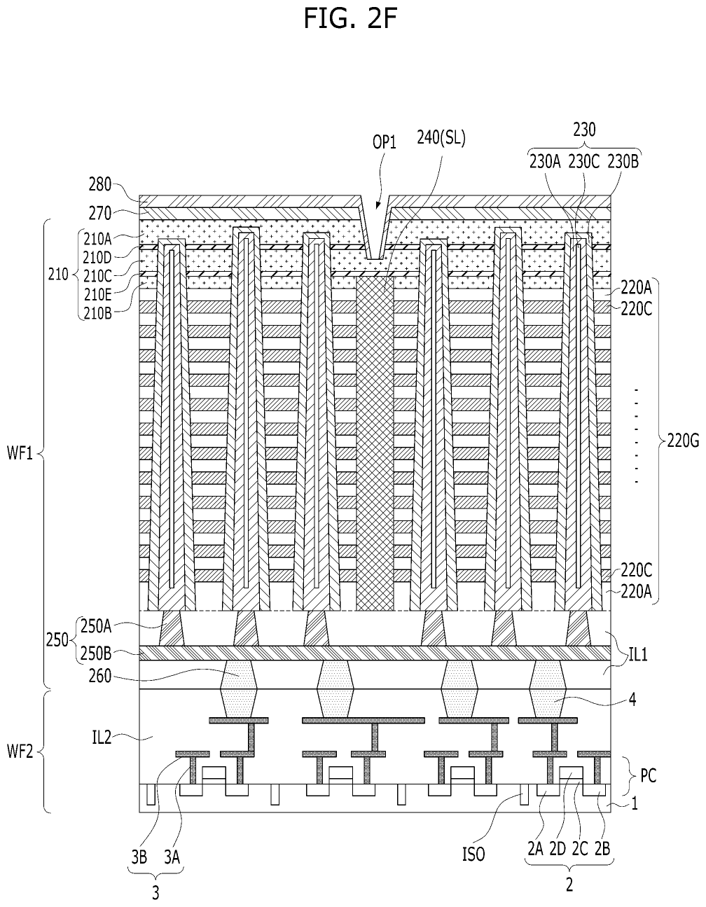

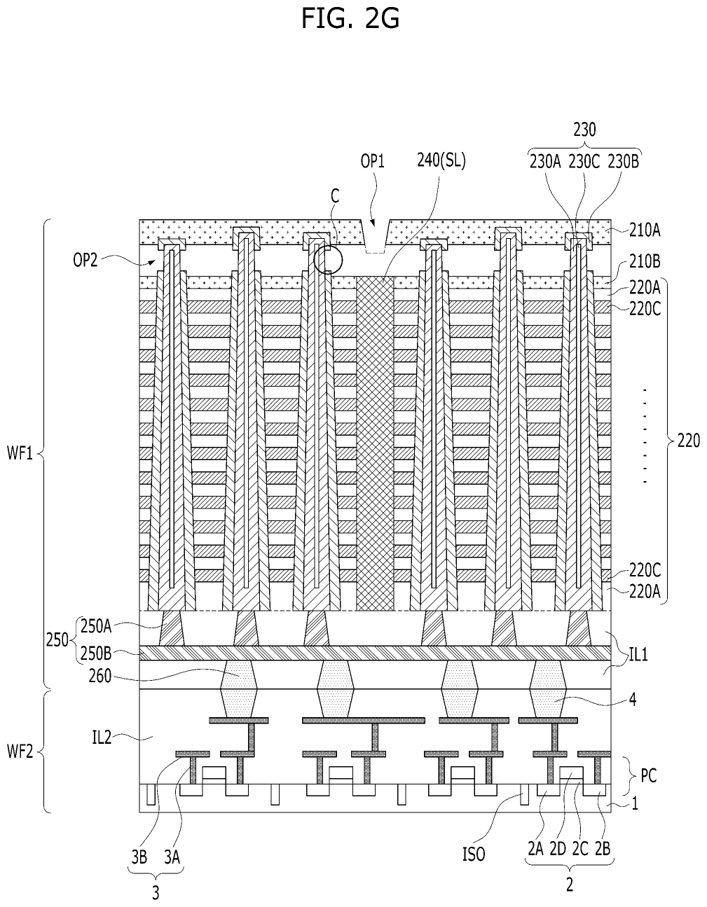

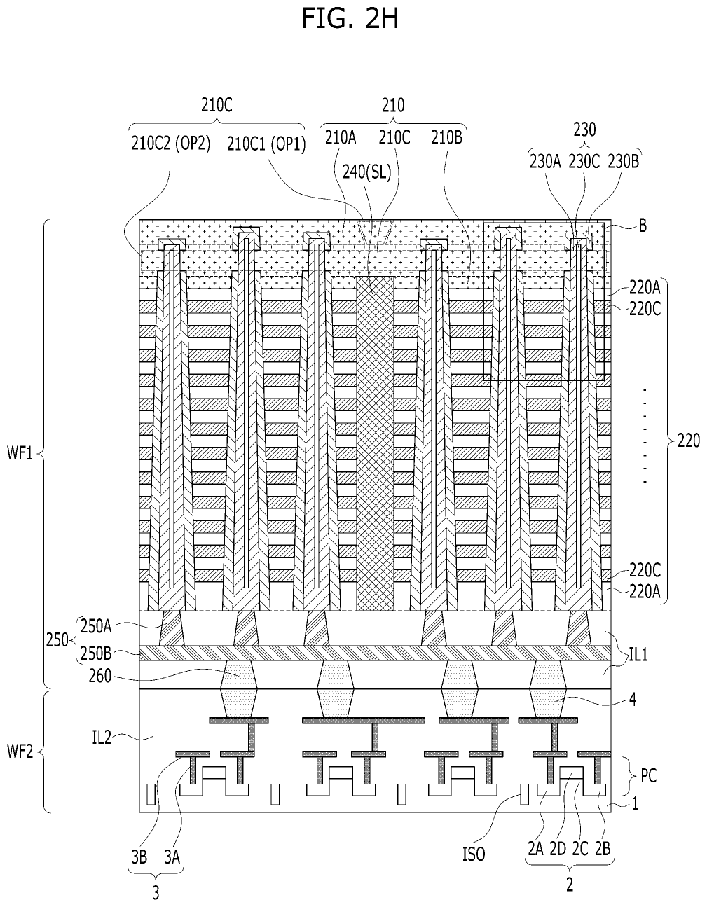

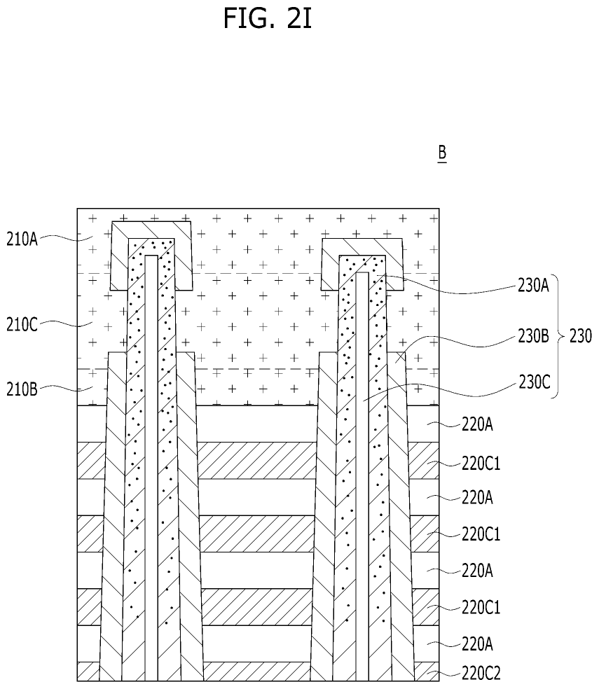

FIGS. 2A to 2I are diagrams for describing a method of manufacturing a semiconductor device according to an embodiment of the present disclosure. Hereinafter, contents that are redundant with the aforementioned contents will be omitted.

Referring to FIG. 2A, a source structure 210 may be formed on a substrate 200. First, a first source layer 210A may be formed on the substrate 200. Next, a source sacrificial layer 210C may be formed over the first source layer 210A. A first protection layer 210D may be formed between the first source layer 210A and the source sacrificial layer 210C. Next, a second source layer 210B may be formed over the source sacrificial layer 210C. A second protection layer 210E may be formed between the source sacrificial layer 210C and the second source layer 210B. In this case, each of the first source layer 210A, the second source layer 210B, the first protection layer 210D, the second protection layer 210E, and the source sacrificial layer 210C may include at least one of sacrificial materials, such as oxide, nitride, and polysilicon. For example, each of the first source layer 210A, the second source layer 210B, and the source sacrificial layer 210C may include polysilicon. Each of the first protection layer 210D and the second protection layer 210E may include oxide. In this case, at least one of the first protection layer 210D and the second protection layer 210E may be constructed as a multi-layer. For example, the first protection layer 210D may include a layer including oxide and a layer including nitride. As another example, each of the first source layer 210A and the second source layer 210B may include polysilicon. The source sacrificial layer 210C may include nitride. Each of the first protection layer 210D and the second protection layer 210E may include oxide. Accordingly, the source structure 210 that includes the first source layer 210A, the second source layer 210B, the source sacrificial layer 210C, the first protection layer 210D, and the second protection layer 210E may be formed.

For reference, before the source structure 210 is formed, a source protection layer 270A may be formed. That is, after the source protection layer 270A is formed on the substrate 200, the source structure 210 may be formed.

Next, a stack 220 may be formed by alternately stacking first material layers 220A and second material layers 220B on the source structure 210. For example, the stack 220 may be formed on the front surface of the source structure 210. The first material layers 220A may include an insulating material, such as oxide. The second material layers 220B may include a sacrificial material, such as nitride.

Next, channel structures 230 that extend into the source structure 210 through the stack 220 may be formed. First, third openings OP3 that extend into the source structure 210 through the stack 220 may be formed. For example, the third openings OP3 that expose the first source layer 210A through the source sacrificial layer 210C may be formed. The heights of the third openings OP3 may be different from each other. For example, at least one of the third openings OP3 may have a first height H1, and at least one of the third openings OP3 may have a second height H2. The first height H1 and the second height H2 may be different from each other. For example, the second height H2 may be smaller than the first height H1. Next, the channel structures 230 may be formed within the third openings OP3, respectively. Each of the channel structures 230 may include at least one of a channel layer 230A, a memory layer 230B that surrounds the channel layer 230A, and an insulating core 230C within the channel layer 230A. Accordingly, each of the channel structures 230 may include at least one of a first channel structure 230_1 having the first height H1 and a second channel structure 230_2 having the second height H2 different from the first height H1.

Referring to FIG. 2B, a slit structure SL may be formed within the stack 220. For example, the slit structure SL that is disposed between the channel structures 230 may be formed within the stack 220. First, a slit SL may be formed within the stack 220. The slit SL may be extended into the source structure 210 through the stack 220. For example, the slit SL may expose the second protection layer 210E. Next, the second material layers 220B of the stack 220 may be substituted with third material layers 220C, respectively, through the slit SL. Accordingly, a gate structure 220G including the first material layers 220A and the third material layers 220C that are alternately stacked may be formed. In this case, the third material layers 220C may include a conductive material, such as tungsten or molybdenum. Each of the third material layers 220C may be used as a source selection line, a drain selection line, a word line, or a bit line.

If the second material layers 220B each includes a conductive material, the second material layers 220B might not be substituted with the third material layers 220C. In this case, the second material layers 220B may be used as the third material layers 220C, and the stack 220 may be used as the gate structure 220G. Next, the slit structure SL may be formed within the slit SL. The slit structure SL may include a source contact structure that is connected to an insulating layer or the source structure 210.

Referring to FIG. 2C, an interlayer insulating layer IL1 may be formed on the gate structure 220G. Next, an interconnection structure 250 may be formed within the interlayer insulating layer IL1. The interconnection structure 250 may include at least one of contact vias 250A and a wire 250B. The contact vias 250A may be connected to the channel structures 230, respectively. The wire 250B may connect the contact vias 250A. Next, bonding pads 260 may be formed on the interconnection structure 250. The bonding pads 260 may be electrically connected to the channel structures 230 and the source structure 210 through the interconnection structure 250.

Referring to FIG. 2D, a second wafer WF2 including a peripheral circuit PC may be formed. First, the peripheral circuit PC may be formed on the substrate 1. An isolation layer ISO may be disposed within the substrate 1. An active area may be defined by the isolation layer ISO. The peripheral circuit PC may include a transistor 2, a register, or a capacitor. The transistor 2 may include at least one of a first junction 2A, a second junction 2B, a gate insulating layer 2C, and a gate electrode 2D. The gate insulating layer 2C may be formed between the substrate 1 and the gate electrode 2D. Each of the gate insulating layer 2C and the isolation layer ISO may include an insulating material, such as oxide or nitride. An interlayer insulating layer IL2 may be formed on the substrate 1. An interconnection structure 3 may be formed within the interlayer insulating layer IL2. Bonding pads 4 may be formed on the interconnection structure 3. The interconnection structure 3 may include at least one of contact vias 3A and a wire 3B. The contact vias 3A may connect the peripheral circuit PC and the wire 3B. The wire 3B may connect the contact vias 3A or may connect the contact via 3A and the bonding pad 4. The bonding pad 4 may be electrically connected to the peripheral circuit PC through the interconnection structure 3. Accordingly, the second wafer WF2 including the peripheral circuit PC may be formed.

Next, the second wafer WF2 and the first wafer WF1 may be bonded. In this case, the first wafer WF1 may include the source structure 210 and the channel structures 230. The top of the second wafer WF2 and the top of the first wafer WF1 may be bonded. For example, the bonding pads 260 of the first wafer WF1 and the bonding pads 4 of the second wafer WF2 may be connected. Accordingly, the peripheral circuit PC of the second wafer WF2 may be electrically connected to the channel structures 230 and the source structure 210 through the bonding pads 4 and 260. The degree of integration of memory in semiconductor devices can be improved by separately forming the first wafer WF1 including a cell array and the second wafer WF2 including the peripheral circuit PC.

Referring to FIG. 2E, the substrate 200 may be removed. For example, the back surface of the source structure 210 may be exposed by removing the substrate 200 of the first wafer WF1. Namely, the first source layer 210A may be exposed.

Next, a source protection layer 270 may be formed on the source structure 210. For example, the source protection layer 270 may be formed on the back surface of the source structure 210, which has been exposed by removing the substrate 200. In this case, the source protection layer 270 may include an insulating material, such as oxide or nitride. For example, the source protection layer 270 may be an oxide layer that has been formed by partially oxidizing the first source layer 210A.

For reference, referring back to FIG. 2A, before the source structure 210 is formed, a source protection layer 270A may be previously formed. After the first wafer WF1 and the second wafer WF2 are bonded, the source protection layer 270A may be exposed by removing the substrate 200. In this case, a process of forming a separate source protection layer 270 on the back surface of the source structure 210 after the substrate 200 is removed may be omitted.

Referring to FIG. 2F, a first opening OP1 that exposes the source sacrificial layer 210C may be formed through the back surface of the source structure 210. For example, the first opening OP1 that exposes the source sacrificial layer 210C through the first source layer 210A and the first protection layer 210D may be formed through the back surface of the source structure 210. The first opening OP1 may be formed at a location corresponding to the slit structure SL. For example, the first opening OP1 may be formed at a location that has been aligned with the slit structure SL.

Next, an insulating spacer 280 may be formed within the first opening OP1. The insulating spacer 280 may include an insulating material, such as oxide or nitride. For example, the insulating spacer 280 may be an oxide layer that has been formed by oxidizing the source protection layer 270, the first source layer 210A, and the first protection layer 210D that are exposed through the first opening OP1. The insulating spacer 280 may be extended along the back surface of the source structure 210. Next, the source sacrificial layer 210C may be exposed by etching a lower surface of the insulating spacer 280.

Referring to FIG. 2G, a second opening OP2 may be formed by removing the source sacrificial layer 210C through the first opening OP1. Next, the channel layer 230A may be exposed by removing the memory layer 230B of each of the channel structures 230 through the second opening OP2. In this case, the source protection layer 270, the first protection layer 210D, and the second protection layer 210E may be removed. Accordingly, the second opening OP2 may be extended. Accordingly, a cut area C that exposes each of the channel layers 230A of the channel structures 230 may be formed. In this case, the cut areas C may be disposed substantially at the same level.

Referring to FIGS. 2H and 2I, a third source layer 210C may be formed. FIG. 2I is an enlarged view of an area ‘B’ in FIG. 2H. For example, the third source layer 210C may be formed (i.e., filled) within the first opening OP1 and the second opening OP2. The third source layer 210C may include a horizontal part 210C2 that is formed within the second opening OP2 and a vertical part 210C1 that is formed within the first opening OP1. The third source layer 210C may be formed to fill the gaps of the cut areas C. Accordingly, the channel layers 230A of the channel structures 230 may be connected to the horizontal part 210C2 of the third source layer 210C. For example, the channel layers 230A of the channel structures 230 may be in contact with the horizontal part 210C2 of the third source layer 210C. The vertical part 210C1 may protrude between the first source layers 210A, and may be formed at a location that has been aligned with the slit structure 240.

The third source layer 210C may include polysilicon including impurities. The impurities may be diffused into the channel layer 230A through the cut areas C in the process of forming the third source layer 210C. For example, in the process of forming the third source layer 210C, a thermal treatment process may be performed. The impurities included in the third source layer 210C may be diffused into the channel layer 230A. In this case, junctions disposed substantially at the same level (i.e., height) within the channel layers 230A may be formed through the cut areas C.

Although the channel structures 230 are formed at different heights, the junctions disposed substantially at the same level within the channel layers 230A may be formed through the cut areas C. Accordingly, the number of source selection lines 220C1 that are used within one gate structure 220G including the channel structures 230 that constitute a memory string may be the same. The remaining third material layers 220C may be used as a word line 220C2 or a drain selection line.

According to the aforementioned manufacturing method, a path along which the process of substituting the second material layers 220B with the third material layers 220C is performed and a path along which the process of forming the third source layer 210C is performed may be different from each other. For example, the process of substituting the second material layers 220B with the third material layers 220C may be performed before bonding, and may be performed through the slit SL. The process of forming the third source layer 210C may be performed before the bonding, and may be performed by forming the first opening OP1 in the back surface of the source structure 210.

Furthermore, although the channel structures 230 have different heights, junctions that are disposed substantially at the same level within the channel layers 230A of the channel structures 230 can be formed. Accordingly, the number of source selection lines 220C1 within the gate structure 220 may be the same.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the following claims. Such substitutions, modifications, and changes may be said to belong to the scope of the present disclosure. Furthermore, the embodiments may be combined to form additional embodiments.

What is claimed is:

1. A semiconductor device comprising:
a gate structure;
a source structure that is disposed on the gate structure;
channel structures that extend into the source structure through the gate structure, wherein the channel structures comprise a channel layer and a memory layer surrounding the channel layer, the memory layer comprising a cut area that exposes the channel layer; and
a slit structure that extends into the source structure through the gate structure between the channel structures, an upper surface of the slit structure being disposed at a lower level than the cut area.

2. The semiconductor device of claim 1, wherein the source structure is in contact with the channel layer through the cut area.

3. The semiconductor device of claim 1, wherein the channel structures comprise:
a first channel structure comprising a first protruding part that protrudes into the source structure by a first height; and
a second channel structure comprising a second protruding part that protrudes into the source structure by a second height.

4. The semiconductor device of claim 3, wherein the first height and the second height are different from each other.

5. The semiconductor device of claim 3, wherein the source structure comprises:
a first part that surrounds the first protruding part;
a second part that surrounds the second protruding part; and
a third part that is in contact with the first channel structure and the second channel structure and protrudes between the first part and the second part.

6. The semiconductor device of claim 5, wherein the third part comprises:
a horizontal part that extends between the gate structure and the first part and between the gate structure and the second part; and
a vertical part that protrudes between the first part and the second part and protrudes from the horizontal part.

7. The semiconductor device of claim 5,
wherein the memory layer comprises:
a first memory pattern that is disposed between the channel layer and the source structure; and
a second memory pattern that is disposed between the channel layer and the gate structure, and
wherein the cut area is defined between the first memory pattern and the second memory pattern.

8. The semiconductor device of claim 7, wherein the first part or the second part surrounds the first memory pattern.

9. The semiconductor device of claim 5, wherein the third part is in contact with the channel layer.

10. The semiconductor device of claim 5, wherein the source structure further comprises a fourth part that is disposed between the third part and the gate structure.

11. The semiconductor device of claim 5, further comprising a junction that is disposed within the channel layer of each of the channel structures having different heights.

12. The semiconductor device of claim 1,
further comprising a second semiconductor structure that is bonded to a first semiconductor structure,
wherein the first semiconductor structure comprises the gate structure, the source structure, the channel structures, and the slit structure, and
wherein the second semiconductor structure comprises a peripheral circuit.

13. A method of manufacturing a semiconductor device, the method comprising:
forming a source structure comprising a source sacrificial layer over a substrate;
forming a stack by alternately stacking first material layers and second material layers on a front surface of the source structure;
forming channel structures that extend into the source structure through the stack;
removing the substrate;
forming a first opening that exposes the source sacrificial layer through a back surface of the source structure;
forming a second opening by removing the source sacrificial layer through the first opening; and
forming a third source layer within the second opening and the first opening.

14. The method of claim 13, wherein the forming of the source structure comprises:
forming a first source layer; and
forming the source sacrificial layer on the first source layer.

15. The method of claim 14, wherein the forming of the source structure further comprises forming a second source layer on the source sacrificial layer.

16. The method of claim 14, wherein the forming of the channel structures comprises:
forming third openings that expose the first source layer through the source sacrificial layer; and
forming channel structures within the third openings, respectively.

17. The method of claim 13, wherein each of the channel structures comprises:
a first channel structure that has a first height and extends into the source structure; and
a second channel structure that has a second height different from the first height and extends into the source structure.

18. The method of claim 13, wherein each of the channel structures comprises:
a channel layer; and
a memory layer that surrounds the channel layer.

19. The method of claim 18, wherein the forming of the third source layer further comprises:
forming a cut area that exposes the channel layer by removing the memory layer through the second opening; and
forming a third source layer that is in contact with the channel layer through the cut area.

20. The method of claim 13, further comprising forming a slit structure that is disposed between the channel structures, within the stack.

21. The method of claim 20, wherein the forming of the slit structure comprises:
forming a slit within the stack;
substituting the second material layers with third material layers, respectively, through the slit; and
forming the slit structure within the slit.

22. The method of claim 20, wherein the first opening is disposed at a location corresponding to the slit structure.

23. The method of claim 13, further comprising forming an insulating spacer within the first opening.

24. The method of claim 23, wherein the insulating spacer extends along the back surface of the source structure.

25. The method of claim 13, wherein the back surface of the source structure is exposed by removing the substrate.

26. The method of claim 25, further comprising forming a source protection layer on the exposed back surface of the source structure.

27. The method of claim 13,
further comprising forming a source protection layer on the substrate before the source structure is formed.

28. The method of claim 27,
wherein the source protection layer is exposed by removing the substrate.

29. The method of claim 13,
further comprising bonding a first wafer in which the source structure and the channel structures are formed and a second wafer that comprises a peripheral circuit,
wherein the substrate is removed after the first wafer and the second wafer are bonded.
